(19) United States
(12) Patent Application Publication
(10) Pub. No.: US 2024/0106439 A1
(43) Pub. Date: Mar. 28, 2024

(54) DELAY LOCKED LOOP, CLOCK SYNCHRONIZATION CIRCUIT AND MEMORY

(71) Applicant: CXMT CORPORATION, Hefei City (CN)

(72) Inventors: Siman LI, Hefei (CN); Yoonjoo EOM, Hefei (CN)

(21) Appl. No.: 18/528,969

(22) Filed: Dec. 5, 2023

Related U.S. Application Data
(63) Continuation of application No. PCT/CN2022/114860, filed on Aug. 25, 2022.

(30) Foreign Application Priority Data
Aug. 11, 2022 (CN) 202210959922.X

(51) Int. Cl. H03L 7/081; G11C 11/4076

(52) U.S. Cl. CPC H03L 7/0812; G11C 11/4076

(57) ABSTRACT

A delay locked loop is provide, including a pre-processing module, a first variable delay line and a phase processing module. The pre-processing module is configured to receive an initial clock signal, pre-process the initial clock signal and output a first clock signal. The first variable delay line is configured to receive the first clock signal, adjust and transmit the first clock signal, and output a first target clock signal. The phase processing module is configured to receive a preset control code and the first target clock signal, perform delay processing on the first target clock signal based on the preset control code, and output at least one delayed target clock signal.

### CROSS-REFERENCE TO RELATED APPLICATIONS

This application is a continuation of International Patent Application No. PCT/CN2022/114860, filed on Aug. 25, 2022, which is based on and claims priority to Chinese patent application No. 202210959922.X, filed on Aug. 11, 2022. The disclosures of International Patent Application No. PCT/CN2022/114860 and Chinese patent application No. 202210959922.X are hereby incorporated by reference in their entireties.

### TECHNICAL FIELD

The present disclosure relates to the technical field of semiconductor memory, in particular to a delay locked loop, a clock synchronization circuit and a memory.

### BACKGROUND

In a Dynamic Random Access Memory (DRAM), a phase synchronization and phase locking of four-phase clock signals (that is, four clock signals whose phases differ by 90 degrees in turn) are required to be performed by a delay locked loop for subsequent generation of target clock signals, and the target clock signals are used for sampling and processing of data signals DQ. In other words, at least four main variable delay lines need to be set in the delay locked loop to realize the calibration of four-phase clock signals, which not only increases a manufacturing cost of a circuit, but also has high power consumption.

### SUMMARY

The present disclosure provides a delay locked loop, a clock synchronization circuit and a memory. The delay locked loop reduces the number of variable delay lines, and can reduce circuit area and power consumption of circuit on the premise of ensuring signal quality.

The technical solutions of the present disclosure are implemented as follows.

According to a first aspect, embodiments of the present disclosure provide a delay locked loop, which includes a pre-processing module, a first variable delay line and a phase processing module.

The pre-processing module is configured to receive an initial clock signal, pre-process the initial clock signal and output a first clock signal.

The first variable delay line is configured to receive the first clock signal, adjust and transmit the first clock signal, and output a first target clock signal.

The phase processing module is configured to receive a preset control code and the first target clock signal, perform delay processing on the first target clock signal based on the preset control code, and output at least one delayed target clock signal.

The first target clock signal and the at least one delayed target clock signal constitute a set of target clock signals; and a phase difference between two adjacent clock signals in the set of target clock signals is a preset value.

According to a second aspect, the embodiments of the present disclosure provide a clock synchronization circuit, including the delay locked loop as described in the first aspect and a data selection module, and signal transmission paths being provided between the delay locked loop and the data selection module.

The delay locked loop is configured to receive an initial clock signal and output a set of target clock signals; and a phase difference between two adjacent clock signals in the set of target clock signals is a preset value.

The data selection module is configured to receive the set of target clock signals via the signal transmission paths, and sample and select data signals for output by using the set of target clock signals to obtain a target data signal.

According to a third aspect, the embodiments of the present disclosure provide a memory, including the clock synchronization circuit as described in the second aspect.

### BRIEF DESCRIPTION OF THE DRAWINGS

FIG. 1 is a structural diagram of a delay locked loop.

FIG. 2 is a signal timing diagram of a delay locked loop.

FIG. 3 is a structural diagram of a delay locked loop provided by an embodiment of the present disclosure.

FIG. 4 is a structural diagram of another delay locked loop provided by an embodiment of the present disclosure.

FIG. 5 is a first local structural diagram of a delay locked loop provided by an embodiment of the present disclosure.

FIG. 6A is a signal timing diagram of a delay locked loop provided by an embodiment of the present disclosure.

FIG. 6B is a signal timing diagram of another delay locked loop provided by an embodiment of the present disclosure.

FIG. 7 is a second local structural diagram of a delay locked loop provided by an embodiment of the present disclosure.

FIG. 8 is a structural diagram of a clock synchronization circuit provided by an embodiment of the present disclosure.

FIG. 9 is a structural diagram of a memory provided by an embodiment of the present disclosure.

### DETAILED DESCRIPTION

The technical solutions in the embodiments of the present disclosure will be clearly and completely described below with reference to the accompanying drawings in the embodiments of the present disclosure. It is to be understood that the specific embodiments described herein are intended only to explain the related application and not to limit the application. In addition, it should be noted that for ease of description, only portions related to the related application are illustrated in the drawings. Unless otherwise defined, all technical and scientific terms used herein have the same meanings as commonly understood by those skilled in the art of the present disclosure. Terms used herein are for the purpose of describing embodiments of the present disclosure only and are not intended to limit the present disclosure. In the following description, “some embodiments” are involved, which describe subsets of all possible embodiments, but it is understood that “some embodiments” may be the same subset or different subsets of all possible embodiments and may be combined with each other without conflict. It should be pointed out that the term “first/second/third” in the embodiments of the present disclosure is only used to distinguish similar objects, and does not represent a particular ordering of objects. It is understood that “first/second/third” may be interchanged in a particular order or priority order where permitted, so that the embodiments of the present disclosure described herein may be implemented in an order other than that illustrated or described herein.

Dynamic Random Access Memory (DRAM);

Synchronous Dynamic Random Access Memory (SDRAM);

Double Data Rate SDRAM (DDR);

Low Power DDR (LPDDR);

The nth generation DDR Specification (DDRn), such as DDR3, DDR4, DDR5, DDR6;

The nth generation LPDDR Specification (LPDDRn), such as LPDDR3, LPDDR4, LPDDR5, LPDDR6.

At present, memories are gradually moving towards high speed development. Taking DDR5 as an example, due to its increasing speed and process limitation, the high-speed clock signal at an interface needs to be converted into a low-speed clock signal internally. For example, the Delay Locked Loop (DLL) in a memory requires a large number of inverter chains to dynamically adjust delays of the clock signals and perform delay matching processing. At high frequency speeds, these inverter chains cause a large accumulation of signal Jitter, which eventually leads to signal loss. Therefore, in order to ensure the signal quality, at the high frequency speed of DDR5, a frequency of the initial clock signal CLK from the outside is divided to obtain four-phase clock signals, and the four-phase clock signals are sent to the delay locked loop respectively for phase synchronization and phase locking, and then data signals DQ are sampled and selected for output by the data selection module (Mux) using the adjusted four-phase clock signals to obtain a target data signal.

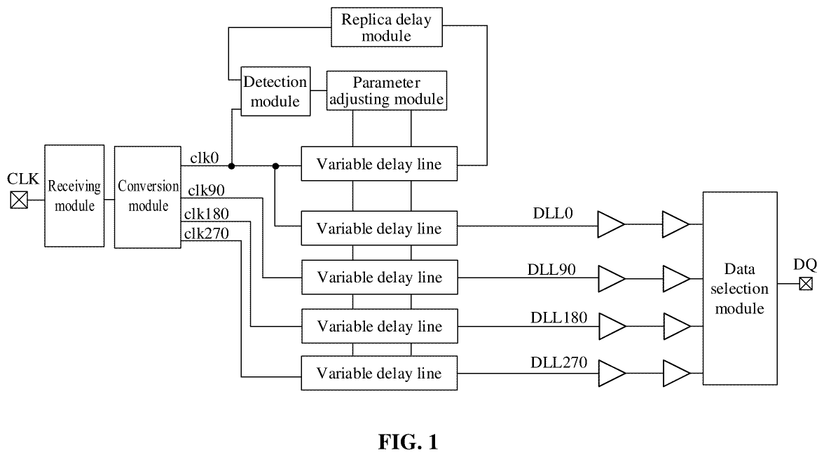

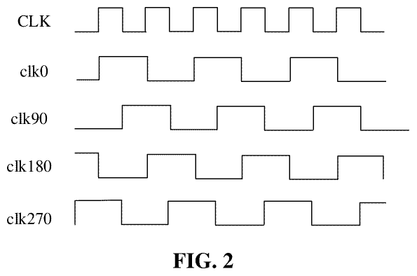

FIG. 1 illustrates a structural diagram of a delay locked loop. FIG. 2 illustrates a signal timing diagram of a delay locked loop. As illustrated in FIG. 1 and FIG. 2, an initial clock signal CLK enters the delay locked loop (DLL) through a receiving module, and is then processed by a conversion module into four-phase clock signals (i.e., clk0, clk90, clk180 and clk270). A frequency of each of the four-phase clock signals is reduced to half of a frequency of the initial clock signal CLK. Then, four variable delay lines are used to delay the four-phase clock signals and adjust the duty cycles of the four-phase clock signals, respectively. In this way, after phase locking performed by the delay locked loop, four-phase target clock signals (i.e., DLL0, DLL90, DLL180 and DLL270) are obtained, and the target clock signals DLL0, DLL90, DLL180 and DLL270 are transmitted to the data selection module via their respective signal transmission paths to realize sampling and selecting of the data signals DQ to output. In addition, the delay locked loop also includes a fifth variable delay line, a replica delay module, a detection module and a parameter adjusting module. The fifth variable delay line and the replica delay module form a loop, and the fifth variable delay line receives the clock signal clk0, the replica delay module outputs a simulation clock signal. The simulation clock signal is configured to simulate a waveform of the target clock signal DLL0 when the target clock signal DLL0 is transmitted to the data selection module. The detection module detects a phase difference between the simulation clock signal and the clock signal clk0. The parameter adjusting module outputs a delay line control signal according to a detection result of the detection module, and the delay line control signal is used to control working parameters of all variable delay lines. In this way, there is a closed-loop feedback mechanism in the delay locked loop, which ensures that the final processed and obtained target clock signals DLL0/DLL90/DLL180/DLL270 meet requirements, and the phases of the target clock signals DLL0/DLL90/DLL180/DLL270 differ by 90 degrees in turn.

From the above, it can be seen that the initial clock signal CLK is divided into four-channel signals to enter the delay locked loop. In order to ensure that the rising edge information and falling edge information of the initial clock signal CLK are not lost, four main variable delay lines need to be provided inside the delay locked loop to so that the four-phase clock signals are synchronized in phase and locked, and finally transmitted to the data selection module (Mux). However, this architecture not only increases the area of the delay locked loop, but also has large power consumption for the delay locked loop. In the actual working scene, after the phase locking performed by the delay locked loop, if the Central Processing Unit (CPU) sends a read command, the four main variable delay lines will continue to work, thus forming an important part of the power consumption of the whole memory. Therefore, on the premise of ensuring signal quality, how to reduce the power consumption of delay locked loop is a difficult problem.

Based on this, embodiments of the present disclosure provide a delay locked loop. The delay locked loop includes a pre-processing module, a first variable delay line and a phase processing module. The pre-processing module is configured to receive an initial clock signal, pre-process the initial clock signal and output a first clock signal. The first variable delay line is configured to receive the first clock signal, adjust and transmit the first clock signal, and output a first target clock signal. The phase processing module is configured to receive a preset control code and the first target clock signal, perform delay processing on the first target clock signal based on the preset control code, and output at least one delayed target clock signal. The first target clock signal and the at least one delayed target clock signal constitute a set of target clock signals; and a phase difference between two adjacent clock signals in the set of target clock signals is a preset value. In this way, the number of variable delay lines in the delay locked loop is reduced on the premise of ensuring signal quality, which can not only reduce the circuit area and reduce the manufacturing cost of circuit, but also reduce the power consumption of the circuit.

Embodiments of the present disclosure will be described in detail below with reference to the accompanying drawings.

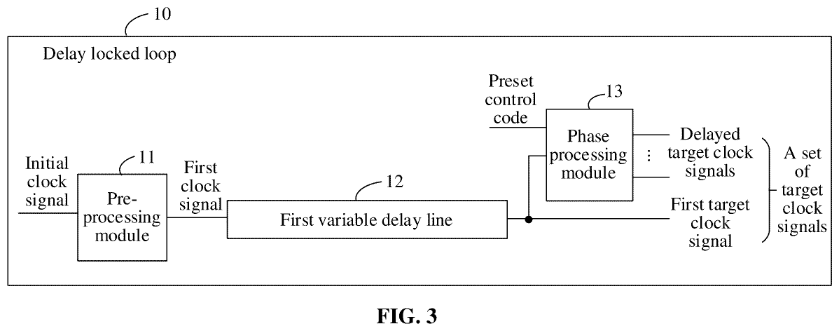

In an embodiment of the present disclosure, FIG. 3 illustrates a structural diagram of a delay locked loop 10 provided by the embodiment of the present disclosure. As illustrated in FIG. 3, the delay locked loop 10 includes a pre-processing module 11, a first variable delay line 12 and a phase processing module 13.

The pre-processing module 11 is configured to receive an initial clock signal, pre-process the initial clock signal and output a first clock signal.

The first variable delay line 12 is configured to receive the first clock signal, adjust and transmit the first clock signal, and output a first target clock signal.

The phase processing module 13 is configured to receive a preset control code and the first target clock signal, perform delay processing on the first target clock signal based on the preset control code, and output at least one delayed target clock signal.

The first target clock signal and the at least one delayed target clock signal constitute a set of target clock signals; and a phase difference between two adjacent clock signals in the set of target clock signals is a preset value.

It should be noted that the delay locked loop 10 of the embodiments of the present disclosure may be applied to, but is not limited to, a memory such as DRAM, SDRAM and the like. In addition, in other analog/digital circuits, a set of clock signals with different phases may be generated by the delay locked loop 10 provided by the embodiments of the present disclosure.

In the delay locked loop 10, the first clock signal is adjusted and transmitted through a first variable delay line 12 to obtain a first target clock signal, and then delay processing is performed through the phase processing module 13 on the first target clock signal to obtain other clock signals in a set of target clock signals. That is to say, only one main variable delay line and a phase processing module need to be provided in the delay locked loop 10 to generate the set of target clock signals. In this way, the number of variable delay lines in the delay locked loop 10 is significantly reduced, which not only reduces the circuit area and deduces a manufacturing cost of the circuit, but also reduces a current and power consumption of the circuit; and further can also improve a phase error caused by mismatch among delay lines, thereby ensuring the signal quality.

It should be understood that the embodiments of the present disclosure allow certain errors for the limitations of phase difference. That is, a phase difference between two adjacent clock signals is a preset value within the allowable error range. Subsequent relevant limitations on phase values, signal alignment, or the same signal waveform refer to be within the allowable error range.

It should be noted that a clock period of each clock signal in a set of target clock signals is twice a clock period of the initial clock signal. According to different actual application requirements, the number M of signals in the set of target clock signals may be determined according to the actual application scenario, and the preset value=360 degrees/M. For example, when M=2, the preset value is 180 degrees, and the at least one delayed target clock signal only include a second target clock signal. Thais, the first target clock signal and the second target clock signal constitute “a set of target clock signals”. For another example, when M=4, the preset value is 90 degrees, the at least one delayed target clock signal includes a second target clock signal, a third target clock signal and a fourth target clock signal. That is, the first target clock signal, the second target clock signal, the third target clock signal and the fourth target clock signal constitute “a set of target clock signals”.

The following uses the set of target clock signals including the first target clock signal (hereinafter DLL0), the second target clock signal (hereinafter DLL90), the third target clock signal (hereinafter DLL180), and the fourth target clock signal (hereinafter DLL270) as an example, and other cases can be understood by reference.

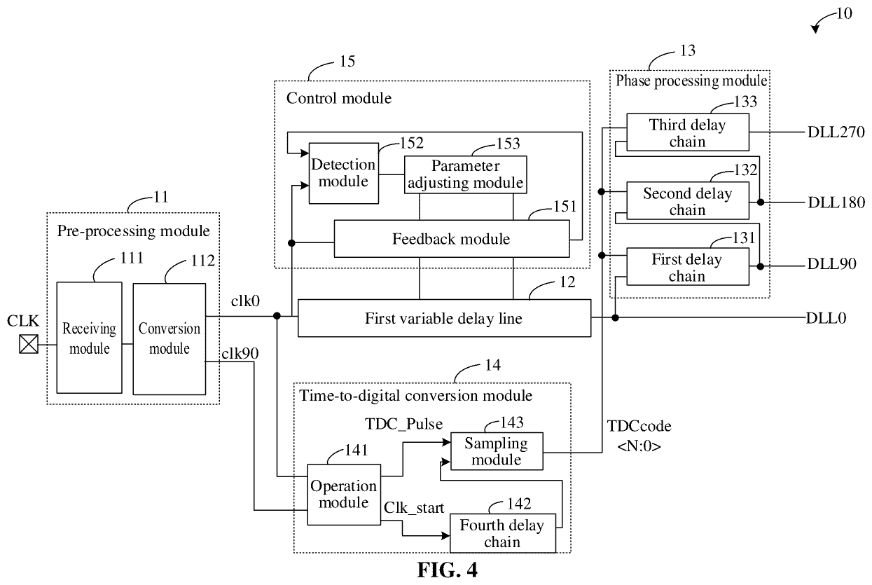

In some embodiments, as illustrated in FIG. 4, the phase processing module 13 includes a first delay chain 131, a second delay chain 132 and a third delay chain 133.

The first delay chain 133 is configured to receive the preset control code TDCcode<N:0> and the first target clock signal DLL0, perform delay processing on the first target clock signal DLL0 based on the preset control code TDCcode<N:0>, and output the second target clock signal DLL90.

The second delay chain 132 is configured to receive the preset control code TDCcode<N:0> and the second target clock signal DLL90, perform delay processing on the second target clock signal DLL90 based on the preset control code TDCcode<N:0>, and output the third target clock signal DLL180.

The third delay chain is configured to receive the preset control code TDCcode<N:0> and the third target clock signal DLL180, perform delay processing on the third target clock signal DLL180 based on the preset control code TDCcode<N:0>, and output the fourth target clock signal DLL270.

It should be noted that the first delay chain 131, the second delay chain 132, and the third delay chain 133 have the same structure, and the preset control code TDCcode<N:0> may control each of the first delay chain 131, the second delay chain 132, and the third delay chain 133 to delay an input signal thereof by 90 degrees, so as to obtain the set of target clock signals with a phase difference of 90 degrees between every two adjacent target clock signals finally.

In some embodiments, as illustrated in FIG. 4, the pre-processing module 11 is specifically configured to perform frequency division processing and phase division processing on the initial clock signal CLK and output a first clock signal clk0 and a second clock signal clk90. A clock period of the first clock signal clk0 is twice a clock period of the initial clock signal CLK, a clock period of the second clock signal clk90 is the same as the clock period of the first clock signal clk0, and a phase difference between the first clock signal clk0 and the second clock signal clk90 is 90 degrees. Accordingly, as illustrated in FIG. 4, the delay locked loop 10 also includes a time-to-digital conversion module 14.

The time-to-digital conversion module 14 is configured to receive the first clock signal clk0 and the second clock signal clk90, and output the preset control code TDCcode<N:0> based on the phase difference between the first clock signal clk0 and the second clock signal clk90.

Since the phase difference between the first clock signal clk0 and the second clock signal clk90 is 90 degrees, the preset control code TDCcode<N:0> determined therefrom can control that the phase of a certain signal is delayed by 90 degrees.

In some implementations, as illustrated in FIG. 4, the pre-processing module 11 includes a receiving module 111 and a conversion module 112.

The receiving module 111 is configured to receive the initial clock signal CLK and output a clock signal to be processed. A clock period of the clock signal to be processed is the same as the clock period of the initial clock signal CLK.

The conversion module 112 is configured to receive the clock signal to be processed, perform frequency division and phase division processing on the clock signal to be processed, and output the first clock signal clk0 and the second clock signal clk90.

It should be noted that the initial clock signal CLK is an externally generated high-frequency clock signal. Due to the limitation of process, the memory (such as DRAM) needs to perform, after receiving the initial clock signal CLK, frequency division processing and phase division processing on the initial clock signal CLK to obtain the low-frequency first clock signal clk0 and the low-frequency second clock signal clk90.

Here, the conversion module 112 may adopt a conventional structure as illustrated in FIG. 1, that is, the conversion module 112 outputs four-phase clock signals actually, including a first clock signal clk0, a second clock signal clk90, a third clock signal clk180, and a fourth clock signal clk270. In this case, any two clock signals with a phase difference of 90 degrees may be used as inputs to the time-to-digital conversion module 14, but attention should be paid to delay matching. Alternatively, the conversion module 112 may be simplified in that the conversion module 112 outputs only the first clock signal clk0 and the second clock signal clk90.

In some embodiments, the preset control code TDCcode<N:0> includes A-bit parameters, i.e., TDCcode <0>, TDCcode <1>, . . . and TDCcode <N>, where A=N+1.

As illustrated in FIG. 4, the time-to-digital conversion module 14 may include an operation module 141, a fourth delay chain 142 and a sampling module 143.

The operation module 141 is configured to receive the first clock signal clk0 and the second clock signal clk90, perform logic operation on the first clock signal clk0 and the second clock signal clk90, and output a sampling base signal TDC_Pulse and a sampling clock signal Clk_start. The sampling base signal TDC_Pulse is used to indicate the phase difference between the first clock signal clk0 and the second clock signal clk90.

The fourth delay chain 142 includes A first delay units connected in series, and is configured to receive the sampling clock signal Clk_start and output A sampling indication signals. An i-th first delay unit in the first delay units outputs an i-th sampling indication signal in the sampling indication signals.

The sampling module 143 is configured to receive the A sampling indication signals and the sampling base signal TDC_Pulse, and perform sampling processing on the sampling base signal TDC_Pulse by using the i-th sampling indication signal, and output an i-th-bit parameter in the preset control code TDCcode<N:0>.

i and A are natural numbers, and i is less than or equal to A.

It should be noted that since the preset control code TDCcode<N:0> is determined via the fourth delay chain 142 based on the phase difference (i.e., 90 degrees) between the first clock signal and the second clock signal, and the first delay chain 131, the second delay chain 132, and the third delay chain 133 have the same structure as the fourth delay chain 142, the preset control code TDCcode<N:0> may control each of the first delay chain 131, the second delay chain 132, and the third delay chain 133 to delay an input signal thereof by 90 degrees. In particular, the time-to-digital conversion module 14 may only need to operate once and then be turned off, and the saved preset control code TDCcode<N:0> may be continuously used during one operation of the memory, thus saving power consumption.

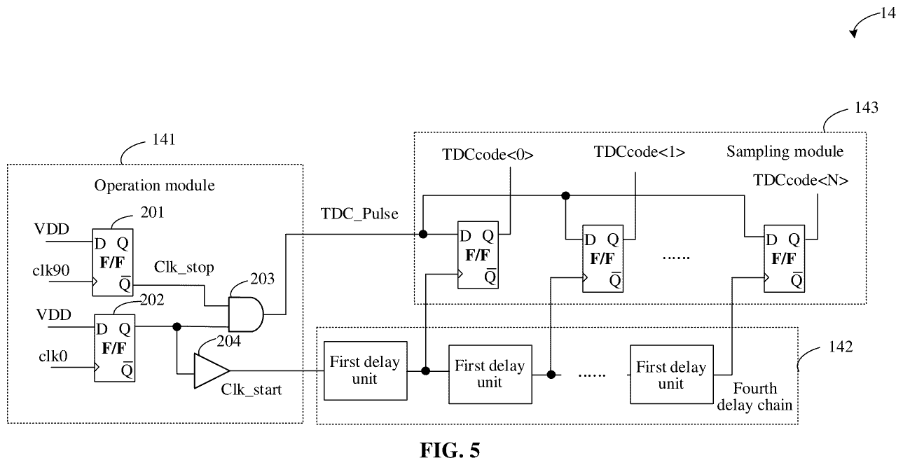

In a specific embodiment, FIG. 5 illustrates a first local structural diagram of a delay locked loop 10 provided by the embodiment of the present disclosure. FIG. 5 is a schematic diagram of a circuit structure of the time-to-digital conversion module 14. As illustrated in FIG. 5, the operation module 141 includes a first flip-flop 201, a second flip-flop 202, an AND gate 203, and a buffer 204.

An input end of the first flip-flop 201 receives a power supply signal VDD, a clock end of the first flip-flop 201 receives the second clock signal clk90, an input end of the second flip-flop 202 receives the power supply signal VDD, and a clock end of the second flip-flop 202 receives the first clock signal clk0.

A first input end of the AND gate 203 is connected with a negative output end of the first flip-flop 201, a second input end of the AND gate 203 is connected with a positive output end of the second flip-flop 202, and an output end of the AND gate 203 is used to output the sampling base signal TDC_Pulse.

An input end of the buffer 204 is connected with the positive output end of the second flip-flop 202, and an output end of the buffer 204 is used to output the sampling clock signal Clk_start.

It should be noted that a signal at the positive output end of a flip-flop is a result of sampling a signal at the input end of the flip-flop on a rising edge of a signal at a clock end. A level state of a signal at the negative output end and a level state of a signal at the positive output end in the flip-flop are opposite. For example, if a signal at the positive output end in the flip-flop is high level, a signal at the negative output end in the flip-flop is low level. If the signal at the positive output end in the flip-flop is low level, the signal at the negative output end in the flip-flop is high level. In addition, each of the flip-flops has a reset end, and an initial state of the flip-flops after reset needs to be determined according to the actual application requirements.

It should be noted that the buffer is a common circuit device, which not only plays a role of delaying signals, but also can increase the driving ability of signals. Here, the signal at the output of the first flip-flop 201 and the signal at the output of the second flip-flop 202 are processed by the AND gate 203 to generate the sampling base signal TDC_Pulse, in which a certain transmission delay occurs. Thus, the signal output by the second flip-flop 202 needs to pass through the buffer 204 to obtain the sampling clock signal Clk_start, so that the sampling clock signal Clk_start is synchronized with the sampling base signal TDC_Pulse. In other words, the buffer 204 may match the delay generated by the AND gate 203, and the buffer 204 may also enhance the driving capability of the sampling clock signal Clk_start.

In addition, a certain number of buffers may be set on a respective transmission link for each of the sampling base signal TDC_Pulse and the sampling clock signal Clk_start to make better delay matching.

In a particular embodiment, as illustrated in FIG. 5, the sampling module 143 includes A third flip-flops (A=N+1). An input end of the i-th third flip-flop receives the sampling base signal TDC_Pulse. A clock end of the i-th third flip-flop is connected with an output end of the i-th first delay unit and is used for receiving the i-th sampling indication signal. A positive output end of the i-th third flip-flop outputs the i-th-bit parameter in the preset control code TDCcode<N:0>.

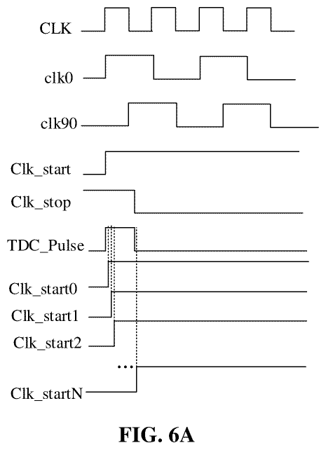

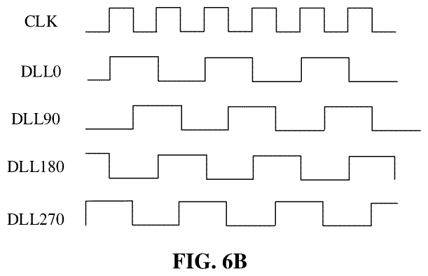

It should be noted that FIG. 6A illustrates a signal timing diagram of a delay locked loop 10 provided by an embodiment of the present disclosure. As illustrated in FIG. 6A, frequency division processing and phase division processing are performed on the initial clock signal CLK to obtain the first clock signal clk0 and the second clock signal clk90. After the time-to-digital conversion module 14 starts operating, the signal Clk_start output by the first flip-flop 201 changes from low level to high level on the first rising edge of the first clock signal clk0, and the signal Clk_stop output by the second flip-flop 202 changes from high level to low level on the first rising edge of the second clock signal clk90 (where the delay of the buffer 204 is ignored temporarily). That is, a duration of high level for the sampling base signal TDC_Pulse is ¼ of a clock period of the “first clock signal clk0 or second clock signal clk90”, and is also equivalent to ½ of a clock period of the “initial clock signal CLK”. In addition, the sampling clock signal Clk_start enters the fourth delay chain 142, passing through the A first delay units sequentially to obtain Clk_start0 (first sampling indication signal), Clk_start1 (second sampling indication signal) . . . , and Clk_startN (A-th first sampling indication signal). The sampling base signal TDC_Pulse is sampled by Clk_start0 to obtain TDCcode<0>, the sampling base signal TDC_Pulse is sampled by Clk_start1 to obtain TDCcode<1> . . . , and the sampling base signal TDC_Pulse is sampled by Clk_startN to obtain TDCcode<N>. In this way the preset control code TDCcode<N:0> capable of delaying an input signal by 90 degrees is obtained.

In some embodiments, the time-to-digital conversion module 14 is further configured to send the preset control code TDCcode<N:0> to the phase processing module 13 after the A third flip-flops complete sampling processing and the delay locked loop 10 completes phase lock.

Exemplarily, after the A third flip-flops complete the sampling process and the delay locked loop 10 completes the phase lock, if CPU sends a read command to the memory, the time-to-digital conversion module 14 sends the preset control code TDCcode<N:0> to the phase processing module 13. In this way, the time-to-digital conversion module 14 may only need to operate once and then be turned off, and the preset control code TDCcode<N:0> is saved. The phase processing module 13 may continuously use the preset control code TDCcode<N:0> to complete phase division processing during one operation of the memory, thus reducing power consumption.

As can be seen from the above, the time-to-digital conversion module 14 takes the rising edges of the first clock signal clk0 and the second clock signal clk90 to generate a sampling base signal TDC_Pulse, uses the first clock signal clk0 to generate a sampling clock signal Clk_start, and passes the sampling clock signal Clk_start through different number of first delay units to generate a plurality of sampling indication signals. Then, the time-to-digital conversion module 14 performs sampling on high level information of the sampling base signal TDC_Pulse sequentially by using the plurality of sampling indication signals to obtain the preset control code TDCcode<N:0>, that is, the preset control code TDCcode<N:0> may indicate a delay of half a clock period (of the initial clock signal CLK).

In this way, by means of the time-to-digital conversion module 14, the delay locked loop 10 converts the initial clock signal CLK into a first target clock signal DLL0, a second target clock signal DLL90, a third target clock signal DLL180, and a fourth target clock signal DLL270. Specific waveforms of the clock signals are illustrated in FIG. 6B.

In a specific embodiment, the first delay chain 131, the second delay chain 132 and the third delay chain 133 each includes A second delay units connected in series, and the i-th-bit parameter in the preset control code TDCcode<N:0> is used to control the i-th second delay unit to be in an open state or a closed state.

The first delay chain 131 is specifically configured to perform delay processing on the first target clock signal DLL0 by using the A second delay units in the open state and output the second target clock signal DLL90.

The second delay chain 132 is specifically configured to perform delay processing on the second target clock signal DLL90 by using A second delay units in the open state and output the third target clock signal DLL180.

The third delay chain 133 is specifically configured to perform delay processing on the third target clock signal DLL180 by using A second delay units in the open state and output the fourth target clock signal DLL270.

In another specific embodiment, first B-bit parameters in the preset control code TDCcode<N:0> are a first value, and last (A-B)-bit parameters of the preset control code TDCcode<N:0> are a second value; where B is a positive integer less than or equal to A.

The first delay chain 131, the second delay chain 132 and the third delay chain 133 each includes A second delay units connected in series, and the preset control code TDCcode<N:0> indicates that an output signal of a B-th second delay unit in the second delay units is used as an output signal of a delay chain.

The first delay chain 131 is specifically configured to receive the first target clock signal DLL0 through a first one in the A second delay units and determine an output signal of a B-th second delay unit in the second delay units as the second target clock signal DLL90.

The second delay chain 132 is specifically configured to receive the second target clock signal DLL90 through a first one in the A second delay units and determine an output signal of a B-th second delay unit in the second delay units as the third target clock signal DLL180.

The third delay chain 133 is specifically configured to receive the third target clock signal DLL180 through a first one in the A second delay units and determine an output signal of a B-th second delay unit in the second delay units as the fourth target clock signal DLL270.

Taking the first delay chain 131 as an example, assuming TDCcode<N:0>=111100, the output end of a fourth second delay unit outputs the second target clock signal DLL90, that is, the second target clock signal DLL90 does not pass through the last two second delay units.

It should be noted that each of the A second delay units connected in series has a same structure as a respective one of the A first delay units connected in series. That is, each of the delay units in the first delay chain 131, each of the delay units in the second delay chain 132, each of the delay units in the third delay chain 133, and each of the delay units in the fourth delay chain 142 are the same correspondingly. For example, the first one of the second delay units in the first delay chain 131, the first one of the second delay units in the second delay chain 132, the first one of the second delay units in the third delay chain 133, and the first one of the first delay units in the fourth delay chain 142 are the same. The second one of the second delay units in the first delay chain 131, the second one of the second delay units in the second delay chain 132, the second one of the second delay units in the third delay chain 133, and the second one of the first delay units in the fourth delay chain 142 are the same, and so on.

In this way, by means of the time-to-digital conversion module 14, only one variable delay line for adjusting the first clock signal is required in the delay locked loop 10, which not only reduces the circuit area and reduces a manufacturing cost of the circuit, but also reduces a current and power consumption of the circuit; and further can also improve a phase error caused by mismatch among delay lines and ensure the signal quality.

In some embodiments, as illustrated in FIG. 4, the delay locked loop 10 further includes a control module 15.

The control module 15 is configured to generate a delay line control signal.

The first variable delay line 12 is specifically configured to receive the delay line control signal, adjust and transmit the first clock signal clk0 based on the delay line control signal, and output the first target clock signal DLL0.

Thus, the first variable delay line 12 makes multiple adjustments to the first clock signal clk0 based on the delay line control signal, so that the duty cycle and phase of the first target clock signal DLL0 meet the requirements, and further the second target clock signal DLL90, the third target clock signal DLL180 and the fourth target clock signal DLL270 generated by the first target clock signal DLL0 also meet the requirements.

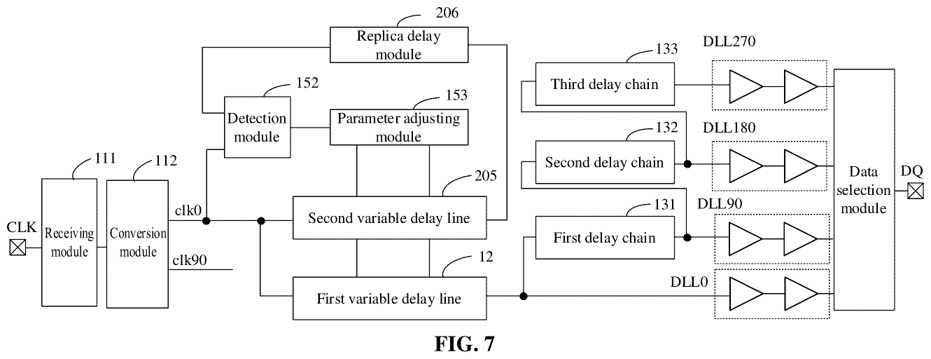

It should be noted that FIG. 7 illustrates a second local structural diagram of a delay locked loop 10 provided by an embodiment of the present disclosure. As illustrated in FIG. 7, the first target clock signal DLL0, the second target clock signal DLL90, the third target clock signal DLL180, and the fourth target clock signal DLL270 are used for data sampling processing after passing through their respective signal transmission paths (see specifically the dashed box portions in FIG. 7). Specifically, the first target clock signal DLL0, the second target clock signal DLL90, the third target clock signal DLL180 and the fourth target clock signal DLL270 passes through the respective signal transmission paths and then arrives at the data selection module (Mux), and the data selection module samples and selects the data signals DQ for output by using the four-phase target clock signals to obtain the target data signal.

Here, a certain number of buffers may be arranged on each signal transmission path to increase the driving ability of signals, and the number of buffers on each of the four signal transmission paths is the same.

Accordingly, as illustrated in FIG. 4, the control module 15 includes a feedback module 151, a detection module 152 and a parameter adjusting module 153.

The feedback module 151 is configured to receive the first clock signal clk0 and output a simulation clock signal, the simulation clock signal being used to simulate a waveform of the first target clock signal DLL0 after passing through the signal transmission path.

The detection module 152 is configured to receive the first clock signal clk0 and the simulation clock signal, perform phase detection on the first clock signal clk0 and the simulation clock signal, and obtain a phase detection signal.

The parameter adjusting module 153 is configured to receive the phase detection signal, and output the delay line control signal based on the phase detection signal.

It should be noted that the waveform of the first target clock signal DLL0 when arriving at the data selection module needs to be consistent with the waveform of the first clock signal clk0, so a feedback adjustment mechanism needs to be constructed. Specifically, a simulation clock signal is generated after the first clock signal clk0 passes through the feedback module 151. Since the simulation clock signal may simulate the waveform of the first target clock signal DLL0 when the first target clock signal DLL0 arrives at the data selection module, the delay line control signal is adjusted according to a difference between the simulation clock signal and the first clock signal clk0, so as to adjust working parameters of the first variable delay line.

In addition, the waveform of the simulation clock signal is not exactly the same with and the waveform of the first target clock signal DLL0 after passing through the signal transmission path. In the actual working scene, after the memory enters a stable operating state, frequency division processing may be performed on the simulation clock signal, thus reducing an update frequency of a delay line adjustment signal, avoiding signal jitter caused by signal burr and reducing power consumption.

In a particular embodiment, as illustrated in FIG. 7, the feedback module 151 includes a second variable delay line 205 and a replica delay module 206.

The second variable delay line 205 is configured to receive the first clock signal clk0 and the delay line control signal, adjust and transmit the first clock signal clk0 based on the delay line control signal, and output a replica clock signal. A structure of the second variable delay line 205 is the same as a structure of the first variable delay line 12, and the replica clock signal is used to simulate the waveform of the first target clock signal DLL0.

The replica delay module 206 is configured to receive the replica clock signal, perform delay processing on the replica clock signal, and output the simulation clock signal. The replica delay module 206 is configured to simulate a delay of the signal transmission path.

Thus, the second variable delay line 205 is used to replicate a processing procedure of the first variable delay line 12, and the replica delay module 206 is at least configured to replicate a delay generated when the first target clock signal DLL0 is transmitted via the signal transmission path, thereby forming a closed loop of feedback adjustment.

To sum up, the embodiments of the present disclosure provides a new structure of a delay locked loop for a high-speed memory, where a time-to-digital conversion module 14 and a phase processing module 13 are introduced into the delay locked loop 10. A delay between the first clock signal and the second clock signal (i.e., half period of the initial clock signal) is measured by the time-to-digital conversion module 14 and converted into a preset control code. After the phase locking performed by the delay locked loop 10, if the CPU sends a read command, the preset control code is sent into a plurality of end-to-end delay chains in the phase processing module 13 to generate four-phase clock signals (including a first target clock signal, a second target clock signal, a third target clock signal and a fourth target clock signal), and the subsequent four-phase target clock signals are used for sampling the data signals DQ. In this way, the number of variable delay lines is reduced on the premise of ensuring signal quality, which can not only reduce the circuit area and reduce the manufacturing cost of the circuit, but also reduce the power consumption of the circuit.

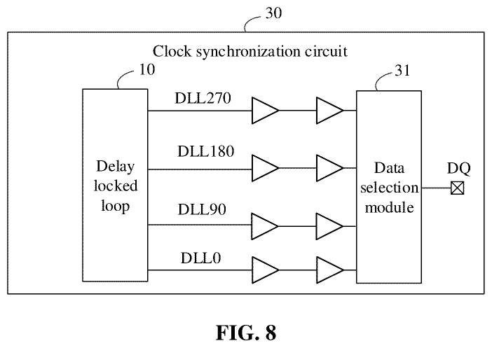

In another embodiment of the present disclosure, FIG. 8 illustrates a structural diagram of a clock synchronization circuit 30 provided by the embodiment of the present disclosure. As illustrated in FIG. 8, the clock synchronization circuit 30 includes the aforementioned delay locked loop 10 and a data selection module 31, and signal transmission paths are provided between the delay locked loop 10 and the data selection module 31.

The delay locked loop 10 is configured to receive an initial clock signal and output a set of target clock signals; a phase difference between two adjacent clock signals in the set of target clock signals is a preset value.

The data selection module 31 is configured to receive the set of target clock signals via the signal transmission paths, and sample and select data signals for output by using the set of target clock signals to obtain a target data signal.

It should be noted that FIG. 8 exemplarily illustrates a set of target clock signals including a first target clock signal DLL0, a second target clock signal DLL90, a third target clock signal DLL180 and a fourth target clock signal DLL270. A phase difference between adjacent two of the first target clock signal DLL0, the second target clock signal DLL90, the third target clock signal DLL180 and the fourth target clock signal DLL270 is 90 degrees in turn. It should be understood that in an actual working scene, the set of target clock signals may include a larger or smaller number of signals.

It should be noted that for a structure of the delay locked loop 10, please refer to the following description. In the delay locked loop 10, the first clock signal is adjusted and transmitted through the first variable delay line to obtain the first target clock signal DLL0, then delay processing is performed on the first target clock signal DLL0 to sequentially obtain other target clock signals in a set of target clock signals (for example, the second target clock signal DLL90, the third target clock signal DLL180, and the fourth target clock signal DLL270). That is to say, for the clock synchronization circuit 30 provided by the embodiment of the present disclosure, only one main variable delay line (in some cases, also including one variable delay line for simulation) and a phase processing module need to be provided in the delay locked loop 10, so as to generate a set of four-phase target clock signals.

In particular, as illustrated in FIG. 8, for all signal transmission paths, the same number of buffers are provided for each signal transmission path to play the role of signal delay and drive enhancement. FIG. 8 exemplarily illustrates that each signal transmission path is provided with two buffers, but more or fewer buffers may be used in practice.

In this way, the number of variable delay lines is reduced on the premise of ensuring signal quality, which can not only reduce the circuit area and reduce the manufacturing cost of the circuit, but also reduce the power consumption of the circuit.

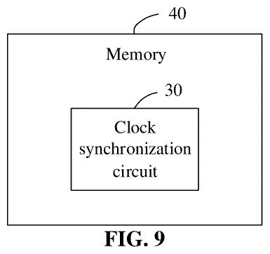

In another embodiment of the present disclosure, FIG. 9 illustrates a composition structural diagram of a memory 40 provided by the embodiment of the present disclosure. As illustrated in FIG. 9, the memory 40 includes at least the aforementioned clock synchronization circuit 30.

It should be noted that since the clock synchronization circuit 30 includes the aforementioned delay locked loop 10, the first clock signal is adjusted and transmitted through a first variable delay line to obtain a first target clock signal, then delay processing is performed on the first target clock signal to sequentially obtain other target clock signals in a set of target clock signals. That is to say, only one main variable delay line (in some cases, also including one variable delay line for simulation) and a phase processing module need to be provided in the delay locked loop 10, so as to generate a set of four-phase target clock signals.

In some embodiments, the memory conforms to at least one of the following specifications: DDR3, DDR4, DDR5, DDR6, LPDDR3, LPDDR4, LPDDR5 or LPDDR6.

It is to be understood that the various modules included in the refresh circuit may be implemented as circuit or sub-circuit, for example, the preprocessing module may be implemented as a preprocessing circuit, the phase processing module may be implemented as phase processing circuit, etc.

In this way, the embodiments of the present disclosure use the architecture of FIG. 3, FIG. 4, FIG. 5 or FIG. 7 to generate a set of target clock signals, which not only ensures the signal quality, but also reduces the circuit area and power consumption of circuit. Because of the high speed of the initial clock signal in the memory, the purpose can be achieved with short delay line, which can reduce nearly half of the power consumption compared with the conventional architecture.

The foregoing is merely preferable embodiments of the present disclosure, and is not intended to limit the scope of protection of the present disclosure. It should be noted that, in the present disclosure, the terms “including”, “comprising” or any other variation thereof are intended to cover non-exclusive inclusion, such that a process, method, article, or apparatus comprising a set of elements includes not only those elements but also other elements not explicitly listed, or also elements inherent to such the process, method, article, or apparatus. In the absence of further limitations, an element defined by the phrase “includes a . . . ” does not preclude the existence of another identical element in the process, method, article or apparatus in which it is included. The above serial numbers of the embodiments of the present disclosure are for description only and do not represent the advantages and disadvantages of the embodiments. The methods disclosed in several method embodiments provided in the present disclosure can be arbitrarily combined without conflict to obtain new method embodiments. The features disclosed in several product embodiments provided in the present disclosure can be arbitrarily combined without conflict to obtain new product embodiments. The features disclosed in several method or device embodiments provided in the present disclosure can be arbitrarily combined without conflict to obtain new method or device embodiments. The above is only the specific implementation of the present disclosure, but the scope of protection of the present disclosure is not limited thereto. Any person skilled in the art can easily think of changes or substitutions within the technical scope disclosed in the present disclosure, which should be covered within the protection scope of the present disclosure. Therefore, the scope of protection of the present disclosure shall be subject to the scope of protection of the claims.

### INDUSTRIAL APPLICABILITY

The embodiments of the present disclosure provide a delay locked loop, a clock synchronization circuit and a memory. The delay locked loop includes a pre-processing module, a first variable delay line and a phase processing module. The pre-processing module is configured to receive an initial clock signal, pre-process the initial clock signal and output a first clock signal. The first variable delay line is configured to receive the first clock signal, adjust and transmit the first clock signal, and output a first target clock signal. The phase processing module is configured to receive a preset control code and the first target clock signal, perform delay processing on the first target clock signal based on the preset control code, and output at least one delayed target clock signal. The first target clock signal and the at least one delayed target clock signal constitute a set of target clock signals; and a phase difference between two adjacent clock signals in the set of target clock signals is a preset value. In this way, the number of variable delay lines in the delay locked loop is reduced on the premise of ensuring signal quality, which can not only reduce the circuit area and reduce the manufacturing cost of the circuit, but also reduce the power consumption of the circuit.

1. A delay locked loop, comprising:
a pre-processing module, configured to receive an initial clock signal, pre-process the initial clock signal and output a first clock signal;
a first variable delay line, configured to receive the first clock signal, adjust and transmit the first clock signal, and output a first target clock signal; and
a phase processing module, configured to receive a preset control code and the first target clock signal, perform delay processing on the first target clock signal based on the preset control code, and output at least one delayed target clock signal;
wherein the first target clock signal and the at least one delayed target clock signal constitute a set of target clock signals; and a phase difference between two adjacent clock signals in the set of target clock signals is a preset value.

2. The delay locked loop of claim 1, wherein the preset value is 90 degrees; and
the at least one delayed target clock signal comprises a second target clock signal, a third target clock signal and a fourth target clock signal.

3. The delay locked loop of claim 2, wherein the phase processing module comprises:
a first delay chain, configured to receive the preset control code and the first target clock signal, perform delay processing on the first target clock signal based on the preset control code, and output the second target clock signal;
a second delay chain, configured to receive the preset control code and the second target clock signal, perform delay processing on the second target clock signal based on the preset control code, and output the third target clock signal; and
a third delay chain, configured to receive the preset control code and the third target clock signal, perform delay processing on the third target clock signal based on the preset control code, and output the fourth target clock signal.

4. The delay locked loop of claim 3, wherein
the pre-processing module is specifically configured to perform frequency division processing and phase division processing on the initial clock signal and output a first clock signal and a second clock signal; wherein a clock period of the first clock signal is twice a clock period of the initial clock signal, a clock period of the second clock signal is the same as the clock period of the first clock signal, and a phase difference between the first clock signal and the second clock signal is 90 degrees;
the delay locked loop further comprising a time-to-digital conversion module; wherein
the time-to-digital conversion module is configured to receive the first clock signal and the second clock signal, and output the preset control code based on the phase difference between the first clock signal and the second clock signal.

5. The delay locked loop of claim 4, wherein the preset control code comprises A-bit parameters, and the time-to-digital conversion module comprises:
an operation module, configured to receive the first clock signal and the second clock signal, perform logic operation on the first clock signal and the second clock signal, and output a sampling base signal and a sampling clock signal; wherein the sampling base signal is used to indicate the phase difference between the first clock signal and the second clock signal;
a fourth delay chain, comprising A first delay units connected in series, configured to receive the sampling clock signal and output A sampling indication signals; wherein an i-th first delay unit in the first delay units outputs an i-th sampling indication signal in the sampling indication signals; and
a sampling module, configured to receive the A sampling indication signals and the sampling base signal, and perform sampling processing on the sampling base signal by using the i-th sampling indication signal, and output an i-th-bit parameter in the preset control code;
wherein i and A are natural numbers, and i is less than or equal to A.

6. The delay locked loop of claim 5, wherein the operation module comprises a first flip-flop, a second flip-flop, an AND gate, and a buffer; wherein
an input end of the first flip-flop receives a power supply signal, a clock end of the first flip-flop receives the second clock signal, an input end of the second flip-flop receives the power supply signal, and a clock end of the second flip-flop receives the first clock signal;
a first input end of the AND gate is connected with a negative output end of the first flip-flop, a second input end of the AND gate is connected with a positive output end of the second flip-flop, and an output end of the AND gate is used to output the sampling base signal; and
an input end of the buffer is connected with a positive output end of the second flip-flop, and an output end of the buffer is used to output the sampling clock signal.

7. The delay locked loop of claim 5, wherein the sampling module comprises A third flip-flops; wherein
an input end of an i-th third flip-flop in the third flip-flops receives the sampling base signal, a clock end of the i-th third flip-flop receives the i-th sampling indication signal, and a positive output end of the i-th third flip-flop outputs the i-th-bit parameter in the preset control code.

8. The delay locked loop of claim 7, wherein
the time-to-digital conversion module is further configured to send the preset control code to the phase processing module after the A third flip-flops complete sampling processing and the delay locked loop completes phase locking processing.

9. The delay locked loop of claim 5, wherein the first delay chain, the second delay chain and the third delay chain each comprises A second delay units connected in series, and the i-th-bit parameter in the preset control code is used to control an i-th second delay unit in the second delay units to be in an open state or a closed state;
the first delay chain is specifically configured to perform delay processing on the first target clock signal by using the A second delay units of the first delay chain in the open state and output the second target clock signal;
the second delay chain is specifically configured to perform delay processing on the second target clock signal by using the A second delay units of the second delay chain in the open state and output the third target clock signal; and
the third delay chain is specifically configured to perform delay processing on the third target clock signal by using the A second delay units of the third delay chain in the open state and output the fourth target clock signal.

10. The delay locked loop of claim 5, wherein first B-bit parameters in the preset control code are a first value, and last (A-B)-bit parameters of the preset control code are a second value; wherein B is a positive integer less than or equal to A;
the first delay chain, the second delay chain and the third delay chain each comprises A second delay units connected in series, and the preset control code indicates that an output signal of a B-th second delay unit in the second delay units is used as an output signal of a delay chain;
the first delay chain is specifically configured to receive the first target clock signal through a first one in the A second delay units of the first delay chain and determine an output signal of a B-th second delay unit in the second delay units as the second target clock signal;
the second delay chain is specifically configured to receive the second target clock signal through a first one in the A second delay units of the second delay chain and determine an output signal of a B-th second delay unit in the second delay units as the third target clock signal; and
the third delay chain is specifically configured to receive the third target clock signal through a first one in the A second delay units of the third delay chain and determine an output signal of a B-th second delay unit in the second delay units as the fourth target clock signal.

11. The delay locked loop of claim 9, wherein
each of the A second delay units connected in series has a same structure as a respective one of the A first delay units connected in series.

12. The delay locked loop of claim 10, wherein
each of the A second delay units connected in series has a same structure as a respective one of the A first delay units connected in series.

13. The delay locked loop of claim 4, wherein the pre-processing module comprises:
a receiving module, configured to receive the initial clock signal and output a clock signal to be processed; wherein a clock period of the clock signal to be processed is the same as the clock period of the initial clock signal; and
a conversion module, configured to receive the clock signal to be processed, perform frequency division and phase division processing on the clock signal to be processed, and output the first clock signal and the second clock signal.

14. The delay locked loop of claim 2, wherein the delay locked loop further comprises a control module; wherein
the control module is configured to generate a delay line control signal; and
the first variable delay line is specifically configured to receive the delay line control signal, adjust and transmit the first clock signal based on the delay line control signal, and output the first target clock signal.

15. The delay locked loop of claim 14, wherein the first target clock signal, the second target clock signal, the third target clock signal and the fourth target clock signal are used for data sampling processing after each passing through a respective signal transmission path;
wherein the control module comprises:
a feedback module, configured to receive the first clock signal and output an simulation clock signal, the simulation clock signal being used to simulate a waveform of the first target clock signal after passing through the signal transmission path;
a detection module, configured to receive the first clock signal and the simulation clock signal, perform phase detection on the first clock signal and the simulation clock signal, and obtain a phase detection signal; and
a parameter adjusting module, configured to receive the phase detection signal, and output the delay line control signal based on the phase detection signal.

16. The delay locked loop of claim 15, wherein the feedback module comprises:
a second variable delay line, configured to receive the first clock signal and the delay line control signal, adjust and transmit the first clock signal based on the delay line control signal, and output a replica clock signal; wherein a structure of the second variable delay line is the same as a structure of the first variable delay line, and the replica clock signal is used to simulate the waveform of the first target clock signal; and
a replica delay module, configured to receive the replica clock signal, perform delay processing on the replica clock signal, and output the simulation clock signal; wherein the replica delay module is configured to simulate a delay of the signal transmission path.

17. A clock synchronization circuit, comprising the delay locked loop of claim 1 and a data selection module, and signal transmission paths being provided between the delay locked loop and the data selection module; wherein
the delay locked loop is configured to receive the initial clock signal and output the set of target clock signals; a phase difference between two adjacent clock signals in the set of target clock signals is a preset value; and
the data selection module is configured to receive the set of target clock signals via the signal transmission paths, and sample and select data signals for output by using the set of target clock signals to obtain a target data signal.

18. A memory, comprising the clock synchronization circuit of claim 17.

19. The memory of claim 18, wherein the memory conforms to a DDR5 specification.
